(19) United States
(12) Patent Application Publication
(10) Pub. No.: US 2010/0104808 A1
(43) Pub. Date: Apr. 29, 2010

(54) Carbon nanotube composite and method for fabricating the same

(75) Inventors: Shou-Shan Fan, Beijing (CN); Kai-Li Jiang, Beijing (CN); Liang Liu, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: Tsinghua University, Beijing City (CN); HON HAI Precision Industry CO., LTD., Tu-Cheng City (TW)

(21) Appl. No.: 12/583,155

(22) Filed: Aug. 13, 2009

(30) Foreign Application Priority Data
Sep. 30, 2008 (CN) 200810216587.4

(51) Int. Cl. B32B 3/30; B32B 9/04; B32B 5/02; B05D 3/02; B05D 1/02; C23C 14/24

(52) U.S. Cl. 428/143; 428/408; 428/338; 427/372.2; 427/421.1; 427/248.1; 977/742

(57) ABSTRACT

A carbon nanotube composite includes a carbon nanotube structure and a number of nanoparticles. The carbon nanotube structure includes a plurality of carbon nanotubes connected to each other via van der Waals force. The nanoparticles are distributed in the carbon nanotube structure. The carbon nanotubes in the carbon nanotube composite are connected to each other to form a carbon nanotube structure and are arranged in an orderly or disorderly fashion.

### BACKGROUND

1. Technical Field

The present disclosure relates to nano-composites and methods for fabricating the same and, in particular, to a carbon nanotube composite and a method for fabricating the same.

2. Description of the Related Art

The discovery of carbon nanotubes has stimulated a great amount of research efforts around the world. Carbon nanotubes are characterized by the near perfect cylindrical structures of seamless graphite. They have been predicted to possess unusual mechanical, electrical, magnetic, catalytic, and capillary properties. A wide range of potential applications has been suggested including uses as one-dimensional conductors for the design of nanoelectronic devices, as reinforcing fibers in polymeric and carbon composite materials, as absorption materials for gases such as hydrogen, and as field emission sources.

Since the discovery of carbon nanotubes, many studies have been carried out in an effort to improve the quality of carbon nanotubes. Synthesis of cost-effective, good quality composite of carbon nanotubes with other materials, remains a challenge.

What is needed, therefore, is a carbon nanotube composite and a method for fabricating the same, which can satisfy the above-described demands.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of one embodiment of a carbon nanotube composite.

FIG. 2 is a scanning electron microscope (SEM) image of a drawn carbon nanotube film used in the carbon nanotube composite of FIG. 1.

FIG. 3 is an SEM image of a pressed carbon nanotube film used in the carbon nanotube composite of FIG. 1 and having a number of carbon nanotube arranged along different orientations.

FIG. 4 is an SEM image of a pressed carbon nanotube film used in the carbon nanotube composite of FIG. 1 and having a number of carbon nanotubes arranged along a same orientation.

FIG. 5 is an SEM image of a flocculated carbon nanotube film used in the carbon nanotube composite of FIG. 1.

FIG. 6 is a flow chart of one embodiment of a method for fabricating the carbon nanotube composite of FIG. 1.

### DETAILED DESCRIPTION

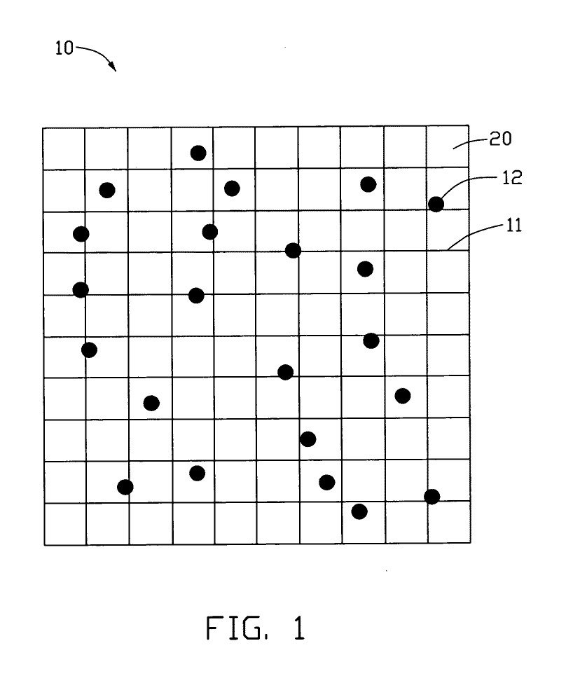

Referring to FIG. 1, one embodiment of a carbon nanotube composite 100 includes a carbon nanotube structure having a number of carbon nanotubes 11 and a number of nanoparticles 12. The carbon nanotubes 11 are connected to one another. Further, the carbon nanotubes 11 and the nanoparticles 12 are uniformly dispersed in the carbon nanotube composite 100.

The carbon nanotube composite 100 has a number of micropores 20. The micropores 20 may be gaps between two adjacent carbon nanotubes 11, gaps between the carbon nanotubes 11 and nanoparticles 12, or gaps between two nanoparticles 12. The micropores 20 may have a diameter or length and width of about 0.3 nanometers (nm) to about 5 millimeters (mm). The micropores 20 in the carbon nanotube composite 100 are advantageous by improving the penetrating capability of the carbon nanotube composite 100 and increasing the aspect ration of the carbon nanotube composite 100.

The carbon nanotubes 11 are distributed in a carbon nanotube structure having at least one carbon nanotube film. When the carbon nanotube structure includes more than one carbon nanotube film, the carbon nanotube films are stacked on top of each other. In one embodiment, the carbon nanotube structure employs more carbon nanotube films to increase the tensile strength of the carbon nanotube composite 100. The carbon nanotube film has a thickness in an approximate range from about 0.5 nm to about 100 mm. The carbon nanotubes films may have a free-standing structure, which means the carbon nanotubes 11 combine, connect, or join with each other via van der Waals attractive force, to form a film structure. The film structure is capable of being supported by itself and does not need a substrate to lie on. The carbon nanotube film can be lifted by one point thereof such as a corner without becoming damaged under its own weight.

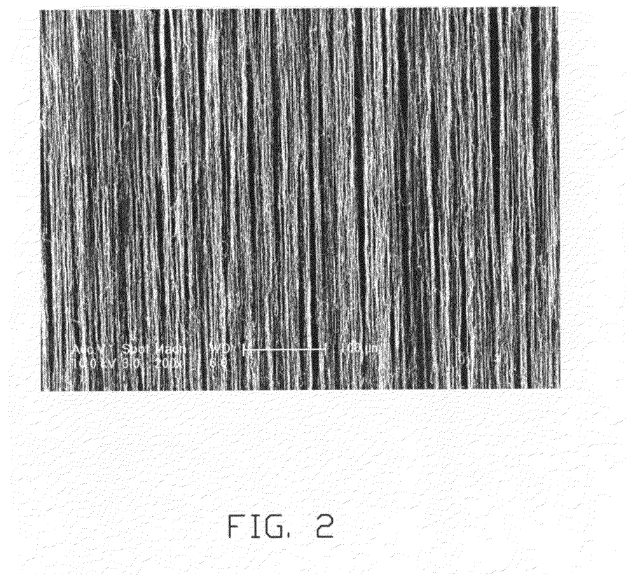

The carbon nanotube films each are formed by the carbon nanotubes 11, with the carbon nanotubes 11 arranged in an orderly or disorderly fashion, and has substantially a uniform thickness. In the ordered films, the ordered carbon nanotube film consists of ordered carbon nanotubes 11. Ordered carbon nanotube films include films where the carbon nanotubes 11 are substantially arranged along a primary direction. Examples include films wherein the carbon nanotubes 11 are arranged approximately along a same direction or have two or more sections within each of which the carbon nanotubes 11 are arranged approximately along a same direction (different sections can have different directions). In the ordered carbon nanotube films, the carbon nanotubes 11 are oriented along a same preferred orientation and approximately parallel to each other. The term “approximately” as used herein means that since it is impossible and unnecessary that each of the carbon nanotubes 11 in the carbon nanotube films be exactly parallel to one another, because in the course of fabricating the carbon nanotube film, some factor, such as the change of drawing speed, and non-uniform drawing force on the carbon nanotube film when the carbon nanotube film is drawn from a carbon nanotube array affects the orientation of the carbon nanotubes 11. A film can be drawn from a carbon nanotube array, to form the ordered carbon nanotube film, namely a drawn carbon nanotube film. Examples of drawn carbon nanotube film are taught by US application 20080170982 to Zhang et al. Referring to FIG. 2, the drawn carbon nanotube film includes a plurality of successive and oriented carbon nanotubes joined end-to-end by van der Waals attractive force therebetween. The drawn carbon nanotube film is a free-standing film. The carbon nanotube film can be treated with an organic solvent to increase the mechanical strength and toughness of the carbon nanotube film and reduce the coefficient of friction of the carbon nanotube film. A thickness of the carbon nanotube film can range from about 0.5 nanometers to about 100 micrometers.

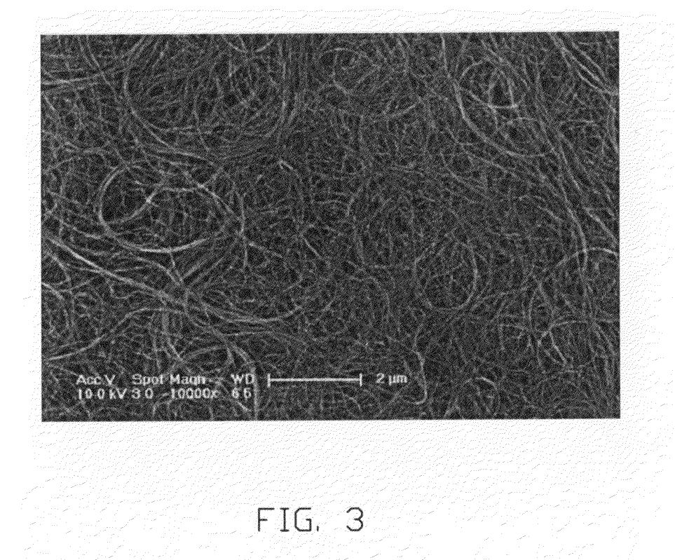

Referring to FIG. 3, the ordered carbon nanotube film may be a pressed carbon nanotube film having a number of carbon nanotubes 11 approximately arranged along a same direction. The carbon nanotubes in the pressed carbon nanotube film can rest upon each other. Adjacent carbon nanotubes are attracted to each other and combined by van der Waals attractive force. An angle between a primary alignment direction of the carbon nanotubes and a surface of the pressed carbon nanotube film is 0 degrees to approximately 15 degrees. The greater the pressure applied, the smaller the angle formed. The thickness of the pressed carbon nanotube film ranges from about 0.5 nm to about 1 mm. Examples of pressed carbon nanotube film are taught by US application 20080299031A1 to Liu et al.

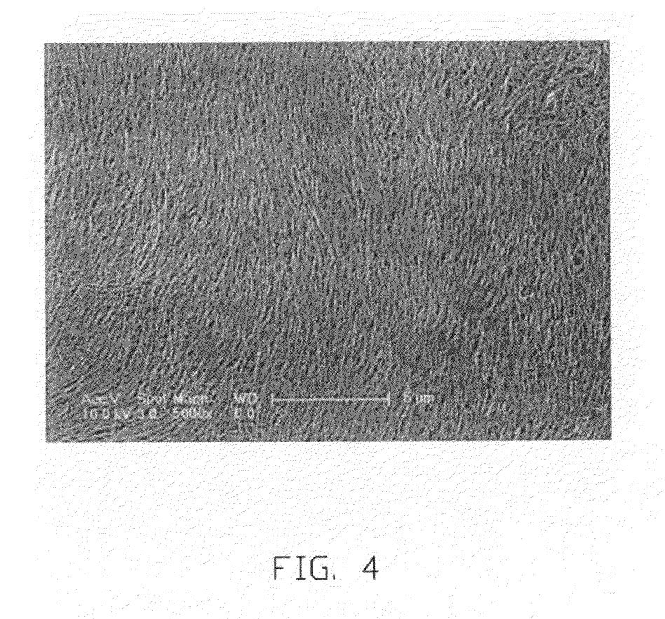

The disordered carbon nanotube film consists of the carbon nanotubes 11 arranged in a disorderly fashion. Disordered carbon nanotube films include randomly aligned carbon nanotubes 11. When the disordered carbon nanotube film comprises of a film in which the number of the carbon nanotubes 11 aligned in every direction is substantially equal, the disordered carbon nanotube film can be isotropic. The disordered carbon nanotubes can be entangled with each other and/or are approximately parallel to a surface of the disordered carbon nanotube film. The disordered carbon nanotube film may be a flocculated carbon nanotube film. Referring to FIG. 4, the flocculated carbon nanotube film can include a plurality of long, curved, disordered carbon nanotubes entangled with each other. Further, the carbon nanotubes 11 in the flocculated carbon nanotube film can be isotropic. The carbon nanotubes 11 can be substantially uniformly dispersed in the flocculated carbon nanotube film. Adjacent carbon nanotubes 11 are attracted by van der Waals attractive force to form an entangled structure with micropores defined therein. It is understood that the flocculated carbon nanotube film is very porous. Sizes of the micropores can be less than 10 micrometers. The porous nature of the flocculated carbon nanotube film will increase specific a surface area of the carbon nanotube structure. Further, due to the carbon nanotubes in the flocculated carbon nanotube film being entangled with each other, the carbon nanotube composite 100 employing the flocculated carbon nanotube film has excellent durability, and can be fashioned into desired shapes with a low risk to the integrity of the flocculated carbon nanotube film. The thickness of the flocculated carbon nanotube film can range from about 0.5 nm to about 1 mm.

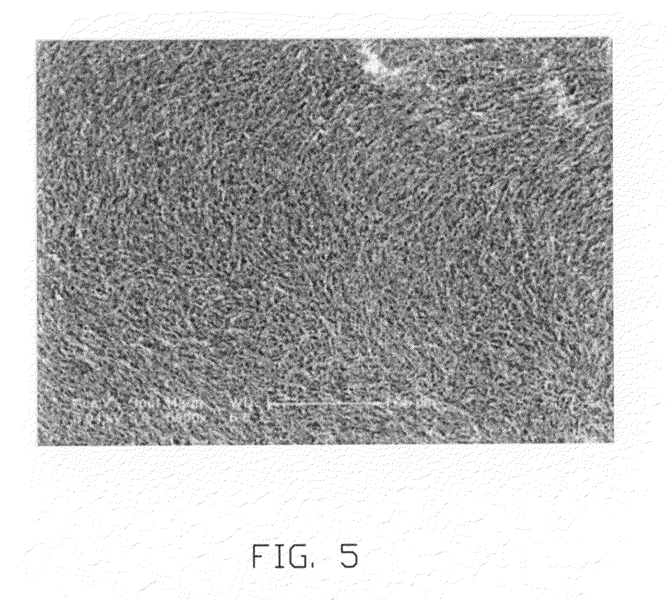

Referring to FIG. 5, the disordered carbon nanotube film may be a pressed carbon nanotube film having a number of carbon nanotubes arranged along different directions. The pressed carbon nanotube film can be a free-standing carbon nanotube film. When the carbon nanotubes in the pressed carbon nanotube film are arranged along different directions, the pressed carbon nanotube film can be isotropic. As described above, the thickness of the pressed carbon nanotube film ranges from about 0.5 nm to about 1 mm. Examples of pressed carbon nanotube film are taught by US application 20080299031A1 to Liu et al.

Length and width of the carbon nanotube film can be arbitrarily set as desired. A thickness of the carbon nanotube film is in a range from about 0.5 nm to about 100 micrometers. The carbon nanotubes in the carbon nanotube film can be single-walled, double-walled, multi-walled carbon nanotubes, and combinations thereof. Diameters of the single-walled carbon nanotubes, the double-walled carbon nanotubes, and the multi-walled carbon nanotubes can, respectively, be in the approximate range from about 0.5 nm to about 50 nm, about 1 nm to about 50 nm, and about 1.5 nm to about 50 nm.

The nanoparticles 12 may be adhered on a surface of the carbon nanotubes 11. When the carbon nanotubes 11 are distributed in a number of carbon nanotube films which may be drawn carbon nanotube films, flocculated carbon nanotube films, pressed carbon nanotube films, or their combinations, the nanoparticles 12 may be dispersed in among the carbon nanotube films. The nanoparticles 12 of the carbon nanotube composite 100 may be isolated from each other, whereby the nanoparticles 12 can have a high specific surface area. Understandably, the nanoparticles 12 may be connected with one another.

The nanoparticles 12 may be nanofibers, nanotubes, nanopods, nanospheres, nanowires, and combinations thereof. The nanoparticles 12 may be made of metal, nonmetal, alloy, metal oxide, polymer, and any combination thereof. The nonmetal may be carbon, diamond, and so on. The alloy may be selected from magnesium alloy, aluminum alloy, and their combination. The metal oxide may be copper oxide, zinc oxide, and so on. The polymer may be polyaniline, polypyrrole, and their combination. In the present embodiment, the nanoparticles 12 are nanospheres made of metal, such as copper (Cu), zinc (Zn), and cobalt (Co). The nanoparticles 12 have a diameter of about 0.3 nm to about 500 nm. The weight percent of the nanoparticles 12 in the carbon nanotube composite 100 is in a range of about 0.01% to about 99%.

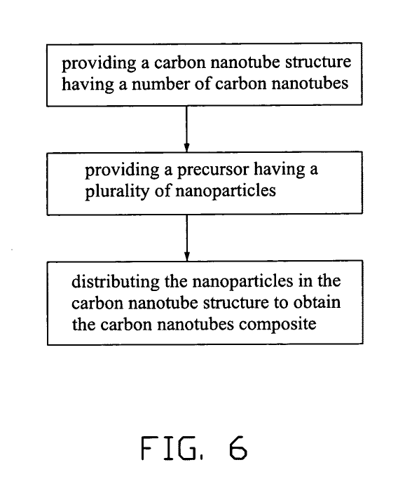

Referring to FIG. 6, one embodiment of a method of manufacturing the carbon nanotube composite 100 is shown. Depending on the embodiment, certain of the steps described below may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps. The method includes:

step S101: providing a carbon nanotube structure having a number of carbon nanotubes 11;

step S102: providing a precursor having a plurality of nanoparticles 12;

step S103: distributing the nanoparticles 12 in the carbon nanotube structure to obtain the carbon nanotubes composite 100.

In step S101, as described above, the carbon nanotube structure has at least carbon nanotube film. The carbon nanotube film can be drawn carbon nanotube film, pressed carbon nanotube film, flocculated carbon nanotube film, or combinations thereof

Since the carbon nanotubes 11 of the carbon nanotube composite 100 form a carbon nanotube structure having a number of carbon nanotube films that are joined with one another, and the carbon nanotubes 11 have good electrical conductivity, the carbon nanotube composite 100 has good electric conductivity. Therefore, the carbon nanotube composite 100 can be employed in electrodes, sensors, shielding material, or the like. Furthermore, due to the carbon nanotube composite 100 having a porous structure, it has a high specific surface area and strong adsorption capacity. Thus, the carbon nanotube composite 100 can be employed as a catalyst carrier.

The drawn carbon nanotube film, the pressed carbon nanotube film and the flocculated carbon nanotube film are fabricated by a different method. Detailed description of methods of these films is followed. The drawn carbon nanotube film can be made by the following steps:

S21: providing an array of carbon nanotubes;

S22: pulling out at least a drawn carbon nanotube film from the carbon nanotube array, and

S23: treating the drawn carbon nanotube film with an organic solvent.

In step S21, the method of forming the array of carbon nanotubes includes:

S211: providing a substantially flat and smooth substrate;

S212: forming a catalyst layer on the substrate;

S213: annealing the substrate with the catalyst at a temperature in the range of about 700° C. to about 900° C. in air for about 30 minutes to about 90 minutes;

S214: heating the substrate with the catalyst at a temperature in the approximate range from about 500° C. to about 740° C. in a furnace with a protective gas therein; and

S215: supplying a carbon source gas to the furnace for about 5 minutes to about 30 minutes and growing a super-aligned array of the carbon nanotubes from the substrate.

In step S211, the substrate can be a P or N-type silicon wafer. In the present embodiment, a 4-inch P-type silicon wafer is used as the substrate.

In step S212, the catalyst can be made of iron (Fe), cobalt (Co), nickel (Ni), or any combination alloy thereof.

In step S214, the protective gas can be made up of at least one of nitrogen (N₂), ammonia (NH₃), and a noble gas.

In step S215, the carbon source gas can be a hydrocarbon gas, such as ethylene (C₂H₄), methane (CH₄), acetylene (C₂H₂), ethane (C₂H₆), or any combination thereof.

In step S22, the drawn carbon nanotube film can be pulled by the steps of:

S221: selecting one or more carbon nanotubes having a predetermined width from the array of carbon nanotubes; and

S222: pulling the carbon nanotubes to form nanotube segments at an even/uniform speed to achieve a uniform carbon nanotube film.

In step 5221, the carbon nanotube segment includes a plurality of approximately parallel carbon nanotubes. The carbon nanotube segments can be selected by using an adhesive tape as the tool to contact the super-aligned array of carbon nanotubes. In step S222, the pulling direction is substantially perpendicular to the growing direction of the super-aligned array of carbon nanotubes.

More specifically, during the pulling process, as the initial carbon nanotube segments are drawn out, other carbon nanotube segments are also drawn out end to end due to van der Waals attractive force between ends of adjacent segments. This process of pulling ensures a substantially continuous and uniform carbon nanotube film having a predetermined width can be formed.

In the step S23, the drawn carbon nanotube film can be treated by applying organic solvent to the drawing carbon nanotube film to soak the entire surface of the carbon nanotube film. The organic solvent is volatile and can be selected from the group consisting of ethanol, methanol, acetone, dichloroethane, chloroform, and any appropriate mixture thereof. In the present embodiment, the organic solvent is ethanol. After being soaked by the organic solvent, adjacent carbon nanotubes in the carbon nanotube film are able to bundle together due to the surface tension of the organic solvent when the organic solvent volatilizes. In another aspect, due to the decrease of the specific surface area via bundling, the mechanical strength and toughness of the drawing carbon nanotube film are increased and the coefficient of friction of the carbon nanotube films is reduced. Macroscopically, the drawing carbon nanotube film will be an approximately uniform film. It is easy to be understood that the step S23 is an optional step.

The width of the drawing carbon nanotube film depends on a size of the carbon nanotube array. The length of the drawing carbon nanotube film can arbitrarily be set as desired. In one embodiment, when the substrate is a 4 inch type wafer as in the present embodiment, a width of the carbon nanotube film is in an approximate range from about 1 centimeter (cm) to about 10 cm, a thickness of the drawing carbon nanotube film is in an range from about 0.5 nm to about 100 microns (μm).

The flocculated carbon nanotube film can be made by the following steps:

step S201: providing a carbon nanotube array;

step S202: separating the array of carbon nanotubes from the substrate to get a plurality of carbon nanotubes;

step S203: adding the plurality of carbon nanotubes to a solvent to get a carbon nanotube floccule structure in the solvent; and

step S204: separating the carbon nanotube floccule structure from the solvent, and shaping the separated carbon nanotube floccule structure into a carbon nanotube film to obtain the flocculated carbon nanotube film.

In step S202, the array of carbon nanotubes is scraped off the substrate by a knife or other similar devices to obtain a plurality of carbon nanotubes. Such a raw material is, to a certain degree, able to maintain the segmented state of the carbon nanotubes. The length of the carbon nanotubes is over 10 μm.

In step S203, the solvent may be water or volatile organic solvent. After adding the plurality of carbon nanotubes to the solvent, a process of flocculating the carbon nanotubes can be executed to create the flocculated carbon nanotube solution. The process of flocculating the carbon nanotubes in the solvent can be by ultrasonic dispersion of the carbon nanotubes and agitating the carbon nanotubes. In this embodiment, ultrasonic dispersion is used to flocculate the solvent containing the carbon nanotubes for about 10 minutes to about 30 minutes. The flocculated and tangled carbon nanotubes form a network structure (i.e., floccule structure), due to the carbon nanotubes in the solvent having a large specific surface area and the tangled carbon nanotubes having a large van der Waals attractive force.

In step S204, the process of separating the floccule structure from the solvent includes the substeps of:

S301: filtering out the solvent to obtain the carbon nanotube floccule structure; and

S302: drying the carbon nanotube floccule structure to obtain the separated carbon nanotube floccule structure.

In step S301, the carbon nanotube floccule structure can be disposed in room temperature for a period of time to dry the organic solvent therein. The time of drying can be selected according to practical needs. The carbon nanotubes in the carbon nanotube floccule structure are tangled together.

In step S302, the process of shaping includes the substeps of:

S401: putting the separated carbon nanotube floccule structure into a container (not shown), and spreading the carbon nanotube floccule structure to form a predetermined structure;

S402: pressing the spread carbon nanotube floccule structure with a certain pressure to yield a desirable shape; and

S403: removing the residual solvent contained in the spread flocculent structure to form the flocculated carbon nanotube film.

After the flocculating step, the carbon nanotubes are tangled together by van der Walls attractive force to form the flocculated carbon nanotube film as shown in FIG. 4. Thus, the flocculated carbon nanotube film has good tensile strength. The flocculated carbon nanotube film includes a plurality of micropores formed by the disordered carbon nanotubes. A diameter of the micropores is less than about 100 microns. As such, a specific area of the flocculated carbon nanotube film is extremely large. Additionally, the flocculated carbon nanotube film is essentially free of binders and includes a large amount of micropores. The method for making the flocculated carbon nanotube film is simple and can be used in mass production.

The pressed carbon nanotube film can be made by the following steps:

S21′: providing a carbon nanotube array and a pressing device; and

S22′: pressing the array of carbon nanotubes to form a pressed carbon nanotube film.

In step S21′, the carbon nanotube array can be made by the same method as S21.

In the step S22′, a certain pressure can be applied to the array of carbon nanotubes by the pressing device. In pressing the array, the carbon nanotubes in the array of carbon nanotubes separate from the substrate and form the carbon nanotube film under pressure. The carbon nanotubes are approximately parallel to a surface of the carbon nanotube film.

In the present embodiment, the pressing device can be a pressure head with a smooth surface. It is to be understood that, the shape of the pressure head and the pressing direction can determine the direction of the carbon nanotubes arranged therein. When a planar pressure head is used to press the array of carbon nanotubes along the direction perpendicular to the substrate, a carbon nanotube film having a plurality of carbon nanotubes isotropically arranged can be obtained. When a roller-shaped pressure head is used to press the array of carbon nanotubes along a certain direction, a carbon nanotube film having a plurality of carbon nanotubes aligned along the certain direction is obtained. When a roller-shaped pressure head is used to press the array of carbon nanotubes along different directions, a carbon nanotube film having a plurality of carbon nanotubes aligned along different directions is obtained.

In step S102, the precursor having the nanoparticles may be a solution or a combination of solid and liquid, and can be made via chemical reaction, such as copper oxide. The nanoparticles may be made of metal, non-metal, alloy, metal oxide, polymer, or the like. The metal may be copper, zinc, cobalt, or the like. The non-metal may be carbon, diamond, or the like. The alloy may be magnesium alloy, aluminum alloy, or the like. The metal oxide may be copper oxide, zinc oxide. The polymer may be polyaniline, polypyrrole, or the like. A solvent of the solution may be water, acid, organic matter, or the like so long as it can dissolve the nanoparticles. In use, the solvent is selected according to the nanoparticles.

In step S103, according to a state of the precursor, different methods may be employed to attach or adhere the nanoparticles 12 on the surface of the carbon nanotubes 11. When the nanoparticles 12 are mixed into a liquid-state material, the liquid-state nanoparticles 12 are attached on the surface of the carbon nanotubes via spraying or evaporation. When the nanoparticles 12 are mixed into a solid-state material, the solid-state nanoparticles 12 are attached on the surface of the carbon nanotube via an evaporating method or a spattering method. In the present embodiment, the nanoparticles 12 are mixed into the liquid-state material, such as water, oil, organic solvent, to form the solution. The method of attaching the nanoparticles 12 of the solution on the carbon nanotubes 11 includes the following steps of:

step S401: immersing the carbon nanotubes structure in the solution having the nanoparticles 12. The carbon nanotube structure can be directly submerged into the solution to immerse the carbon nanotubes 11. Alternatively, the solution can also be dropped or sprayed onto the surface of the carbon nanotubes layer for a period time to apply the nanoparticles 12 to the carbon nanotubes 11.

step S402: removing a solvent of the solution at a predetermined temperature to attach the nanoparticles 12 onto the carbon nanotubes 11. The nanoparticles 12 can attach onto the carbon nanotubes 11 because of van der Waals force between the carbon nanotubes 11 and the nanoparticles 12. It is appreciated that the solution can also contain paste dispersed therein so the nanoparticles 12 will adhere to the carbon nanotubes 11 with a strong binding force.

As described above, the carbon nanotube composite 100 is obtained. The carbon nanotube composite 100 and the method have the following advantages. Firstly, the mechanical strength and toughness of the carbon nanotube composite 100 is improved because the carbon nanotubes in the carbon nanotube composite 100 are connected to each other to form a carbon nanotube structure and arranged orderly or disorderly, which overcomes the entanglement of the carbon nanotubes. Secondly, good conductivity is achieved for the carbon nanotube composite 100 because the carbon nanotubes 11 are employed as a frame of the carbon nanotube composite 10. Finally, fewer or no the carbon nanotubes are destroyed because it is unnecessary to use high temperatures to process or surface treat the carbon nanotube.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A carbon nanotube composite comprising:
a carbon nanotube structure comprising a plurality of carbon nanotubes connected to each other via van der Waals force; and
a plurality of nanoparticles distributed in the carbon nanotube structure.

2. The carbon nanotube composite as claimed in claim 1, wherein the carbon nanotube structure has a free-standing structure.

3. The carbon nanotube composite as claimed in claim 1, wherein the nanoparticles attach to a surface of the carbon nanotubes.

4. The carbon nanotube composite as claimed in claim 1, wherein the plurality of carbon nanotubes is orderly or disorderly arranged into a carbon nanotube layer.

5. The carbon nanotube composite as claimed in claim 4, wherein the carbon nanotube structure comprises at least one carbon nanotube film, the at least one carbon nanotube film comprises a plurality of carbon nanotubes joined end to end via van der Waals force.

6. The carbon nanotube composite as claimed in claim 4, wherein the carbon nanotube structure is a drawn carbon nanotube film, a pressed carbon nanotube film, a flocculated carbon nanotube film, or combinations thereof.

7. The carbon nanotube composite as claimed in claim 6, wherein the carbon nanotube structure is the drawn carbon nanotube film comprising a plurality of carbon nanotubes approximately parallel to each other.

8. The carbon nanotube composite as claimed in claim 1, wherein the nanoparticles are selected from the group consisting of nanofiber, nanotube, nanopod, nano-sphericity, nanowire, and combinations thereof

9. The carbon nanotube composite as claimed in claim 8, wherein the nanoparticles are made of a material selected from the group consisting of metal, nonmetal, alloy, metal oxide, polymer, and combinations thereof

10. The carbon nanotube composite as claimed in claim 1, wherein the nanoparticles have a diameter of about 0.3 nm to about 500 nm.

11. The carbon nanotube composite as claimed in claim 1, wherein the nanoparticles in the carbon nanotube composite have a weight percent of about 0.01% to about 99%.

12. The carbon nanotube composite as claimed in claim 1, wherein the carbon nanotube composite defines a plurality of micropores that have diameters of about 0.3 nm to about 5 mm.

13. A method of manufacturing a carbon nanotube composite, comprising:
providing a precursor having a plurality of nanoparticles;
providing a free-standing carbon nanotube structure having a plurality of carbon nanotubes; and
distributing the nanoparticles in the carbon nanotube structure to obtain the carbon nanotube composite.

14. The method as claimed in claim 13, wherein the precursor is a solution having the nanoparticles dispersed therein, the method of distributing the nanoparticles dispersed in the solution in the carbon nanotube structure comprise:
immersing the carbon nanotube structure into the solution having the nanoparticles dispersed therein; and
removing a solvent of the solution at a predetermined temperature to obtain the carbon nanotube composite.

15. The method as claimed in claim 13, wherein the nanoparticles are made of liquid-state material, the liquid-state nanoparticle is distributed in the carbon nanotube structure via a spraying method or an evaporating method.

16. The method as claimed in claim 13, whererin the nanoparticles are made of solid-state material, the solid-state nanoparticles are distributed in the carbon nanotube structure via an evaporating method or a spattering method.
